(19) United States
(12) Patent Application Publication
(10) Pub. No.: US 2005/0274943 A1
(43) Pub. Date: Dec. 15, 2005

(54) Organic bistable memory and method of manufacturing the same

(76) Inventor: Wei-Su Chen, Hsinchu (TW)

Correspondence Address: HARNESS, DICKEY & PIERCE, P.L.C., P.O. BOX 8910, RESTON, VA, 20195, US

(21) Appl. No.: 10/978,534

(22) Filed: Nov. 2, 2004

(30) Foreign Application Priority Data
Jun. 10, 2004 (TW) 93116692

(51) Int. Cl. G11C 11/36

(52) U.S. Cl. 257/40

(57) ABSTRACT

An organic bistable memory device has an organic layer with two sides, each having a dielectric layer with an electrode. When voltage is applied to the two electrodes, the memory may be switched and operated between a high impedance state and a low impedance state. This reduces negative effects on the memory device due to poor quality material or non-uniform manufacturing of the device, effects such as reduced on/off current ratio, shortened retention time and shorting failure in the device. Also, the disclosed organic bistable memory provides evidence to improve our understanding of bistable memory.

This Non-provisional application claims priority under 35 U.S.C. § 119(a) on Patent Application No(s). 093116692 filed in Taiwan on Jun. 10, 2004, the entire contents of which are hereby incorporated by reference.

### BACKGROUND OF THE INVENTION

1. Field of Invention

The invention relates to a memory device, and particularly to an organic bistable memory device.

2. Related Art

Memory is indispensable to a modem computer. Integration degree of dynamic random access memory (DRAM) may be an important index to semiconductor technology. Organic materials have recently been introduced and used in memory in order to achieve higher integration and power saving purposes.

Among organic memory devices, the organic bistable device (OBD) is a promising memory device. Patent # WO0237500 has disclosed organic bistable memory that has the disadvantage of being difficult to control because of varying quality of the organic material used and conditions of manufacturing the memory device.

However, research has indicated that organic bistable memory is very dependent upon the material used and the degree of vaporization when manufacturing the memory. Organic materials of good quality used for the memory may increase the on/off current ratio of the memory and prolong retention time, while organic materials of inferior quality may lead to a reduced retention time of the memory. In addition, poor materials used for the organic bistable memory commonly cause shorting failure in which the current-voltage relation is kept in an on state. In addition, variations occurring in the conditions of the vaporization process or the process chamber for the manufacture of the organic material may also cause variation of three orders in the on/off current ratio.

Therefore, the materials used and the manufacturing process utilized can be the most challenging issues in the manufacturing technology of organic memory, which urgently need to be overcome.

### SUMMARY OF THE INVENTION

In view of the foregoing problems, an object of the invention is to provide organic bistable memory, which may operate in a high impedance state and a low impedance state to overcome the disadvantages existing in the prior art. In the invention, a compound consisting of an element of Group IA and an element of Group VII or an element of Group IIA and an element of Group VIA is used as a dielectric layer and embedded in the organic memory in order to provide experimental evidence to exhibit possibilities of current transmission in the organic memory.

Therefore, to achieve the above mentioned object, the organic bistable memory which operates between a high impedance state and a low impedance state when a voltage is applied on the organic bistable memory comprises a bistable body formed by an organic material of high impedance and a conductive layer of low impedance; at least a first dielectric layer formed over a surface of the bistable body; at least a second dielectric layer formed over another surface of the bistable body; a first electrode formed below the first dielectric layer and a second electrode formed over the second dielectric layer.

According to the principle and the object of the invention, the organic bistable memory comprises a bistable body formed by an organic material of low impedance and a conductive layer of high impedance and comprising a conductive layer having a dielectric layer formed on one side thereof and a dielectric layer formed on the other side thereof; a first organic layer and a second organic layer formed on one and the other side of the conductive layer, respectively; at least a second dielectric layer formed over another surface of the bistable body; a first electrode formed below the first dielectric layer and a second electrode formed over the second dielectric layer.

According to the invention, each of the first and second dielectric layers has a thickness of 0.5 nm to 50 nm.

To achieve the abovementioned object, a method of manufacturing the organic bistable memory comprises the following steps: vaporizing a first electrode; vaporizing a first organic layer on the first electrode; vaporizing at least a first dielectric layer, a conductive layer and at least a second dielectric layer on the first organic layer, where a vaporizing crucible of the material of the dielectric layer and a vaporizing crucible of the material of the conductive layer are placed in a same process chamber; vaporizing a second organic layer on the second dielectric layer and vaporizing a second electrode on the second organic layer.

According to the principle of the invention, the effects of poor quality material or unstable manufacturing processes may be reduced and screened.

According to the principle of the invention, the reduced on/off current ratio of the memory device caused by poor quality material and shortened retention time may be eliminated.

According to the principle of the invention, the dielectric layers have a protective effect on the organic material.

Other features and advantages will be described in the following detailed description, which may be readily realized from the content, claims and drawings disclosed in the specification and may enable a skilled person of the art to realize and implement the present invention.

### BRIEF DESCRIPTION OF THE DRAWINGS

The foregoing, as well as additional objects, features and advantages of the invention will be more readily apparent from the following detailed description, which proceeds with reference to the accompanying drawings.

FIG. 1 is a structural schematic of a first embodiment of organic bistable memory according to the invention;

FIG. 2 is a structural schematic of a second embodiment of the organic bistable memory according to the invention;

FIG. 3 is a structural schematic of a third embodiment of the organic bistable memory according to the invention;

FIG. 4 is a diagram depicting the voltage-current relation of the organic bistable memory according to the invention;

FIG. 5 is a diagram depicting the voltage-current relation, comparing the organic bistable memory of the invention with the prior art;

FIG. 6 is a diagram depicting the voltage-current relation for dielectric layers with different thicknesses; and

FIG. 7 is the organic bistable memory according to the invention where the dielectric layer thereof has a protective or flattening effect on the surface of an organic layer thereof.

### DETAILED DESCRIPTION OF THE INVENTION

The present invention will become more fully understood from the detailed description given in the illustration below only, and is thus not limitative of the present invention.

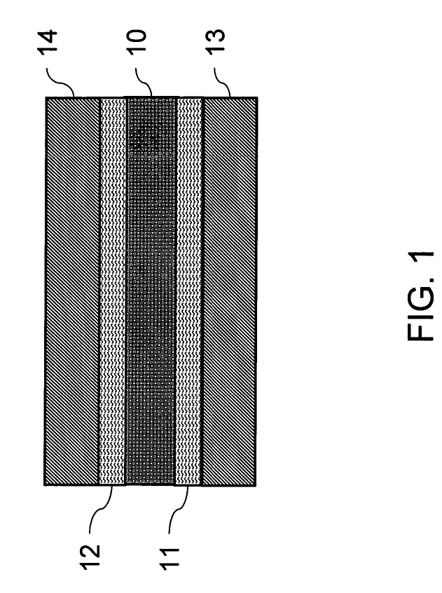

Reference is made to FIG. 1, which is a structural schematic of a first embodiment of organic bistable memory according to the invention. The first embodiment of the organic bistable memory comprises a bistable body 10 having a first dielectric layer 11 and a second dielectric layer 12 formed on two sides of the body respectively. The side of the first dielectric layer 11 not in contact with the bistable body 10 is formed with a first electrode 13, and the side of the second dielectric layer 12 not in contact with the bistable body 10 is formed with a second electrode 14. Although the layers on the sides of the bistable body 10 are stacked in lamination, other shapes or formation may be possible. The bistable body 10 is composed of low conduction and high conduction material having bistable characteristics.

The bistable memory according to the invention may be operated in two states, a high impedance state and a low impedance state, representing 0 and 1 respectively. When voltage is applied on the electrodes of the memory, the memory operates between high and low impedance states. Thus, the memorial function may be achieved.

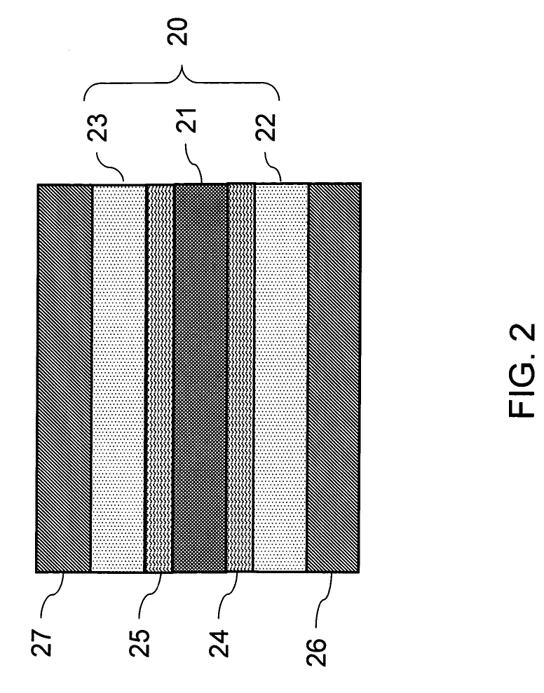

Reference is made to FIG. 2, which is a structural schematic of a second embodiment of the organic bistable memory according to the invention. The embodiment comprises a bistable body 20 with a conductive layer 21, a first organic layer 22 and a second organic layer 23. On two sides of the conductive layer 21, a first dielectric layer 24 and a second dielectric layer 25 are respectively formed. The side of the first organic layer 22 not in contact with the bistable body 20 is formed with a first electrode 26, and the side of the second organic layer 23 not in contact with the bistable body 20 is formed with a second electrode 27.

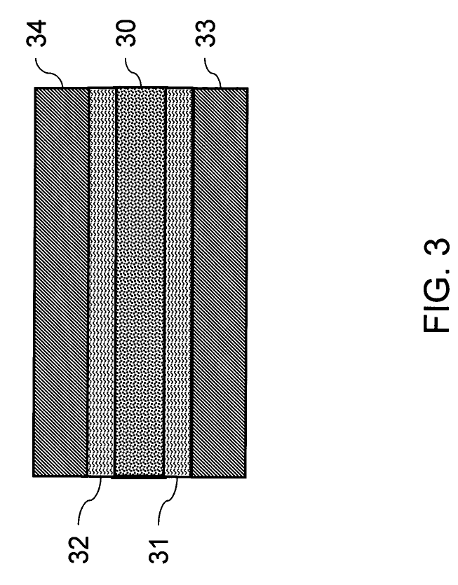

Refer to FIG. 3, which is a structural schematic of a third embodiment of the organic bistable memory according to the invention. This embodiment comprises a bistable body 30 composed of a material with nanoparticles of high conduction and a material of low conduction. On two sides of the bistable body 30, a first dielectric layer 31 and a second dielectric layer 32 are formed. The side of the first dielectric layer 31 not in contact with the bistable body 30 is formed with a first electrode 33, and the side of the second dielectric layer 32 not in contact with the bistable body 30 is formed with a second electrode 34.

According to the invention, the conductive layers and the organic layers in the first, second, and third embodiments are the same. The conductive layer may be a material of high conduction, such as metal and super-conductive material, which may be aluminum, copper or silver. Other materials with high work function such as gold and nickel, materials with middle work function such as magnesium and indium and materials with low work function such as calcium and lithium may be also used as the conductive layer. In addition, an alloy composed of the above metals may be used. An oxide with conduction properties such as metal oxide, a polymer such as PEDOT (3,4-polyethylenedioxy-thiophenepolystyrene-sulfonate and an organic semiconductor such as buckminsterfullerene may be used. The organic layer may be formed with a material of low conduction such as an organic semiconductor or an organic insulator, in which the organic semiconductor may be selected from 2-amino-4,5-imidazoledicarbonitrile (AIDCN), tris-8-(hydroxyquinoline)aluminum (Alq), 7,7,8,8-tetracyanoquino-dimethane (TCNQ) or 3-amino-5-hydroxypyrazole(AHP). Further, the organic semiconductor may be formed with oligomers such as (Polyanaline) ∘ The organic insulator may be a polymer such as polystyrene (PS), polycarbonate (PC), polymethylmethacrylate (PMMA), polyolefines, polyesters, polyamides, polyimides, polyurethanes, polyaccetals, polysilicones or polysulfonates. Other semi-conductive polymers may be used as the organic insulator, such as poly-phenylenevinylene (PPV), polyfluorene (PF), polythiophene (PT), poly-paraphenylene (PPP) and their derivatives.

The first and the second dielectric layers are formed with a compound formed by an element selected from group IA and an element selected from group VIIA or an element from group IIA and group VIA such as lithium fluoride (LiF) or magnesium oxide (MgO), which is very thin, about 0.5 nm˜50 nm, and may take the form of a single layer or multi-layers.

For the lithium fluoride dielectrics, J. Appl. Phys. V. 84, pp. 6729-6736 (1998) suggests that lithium fluoride may connect with Al to cause band bending by virtue of different contact potentials between Al and lithium fluoride. The band bending of lithium fluoride reduces the functionality of the interface between the Al and lithium fluoride, increases electron injection capabilities, and even forms ohmic contact between the Al and lithium fluoride.

If Al nano-particles are used as the material of high conduction according to the invention, when a thin compound formed with an element from IA group and an element from VIIA group or an element from Group IIA and Group VIA, such as lithium fluoride of a thickness of 1.2 nm, is formed on the two sides of the bistable body, and electron injection capability is greatly promoted, as stated in the afore-mentioned literature.

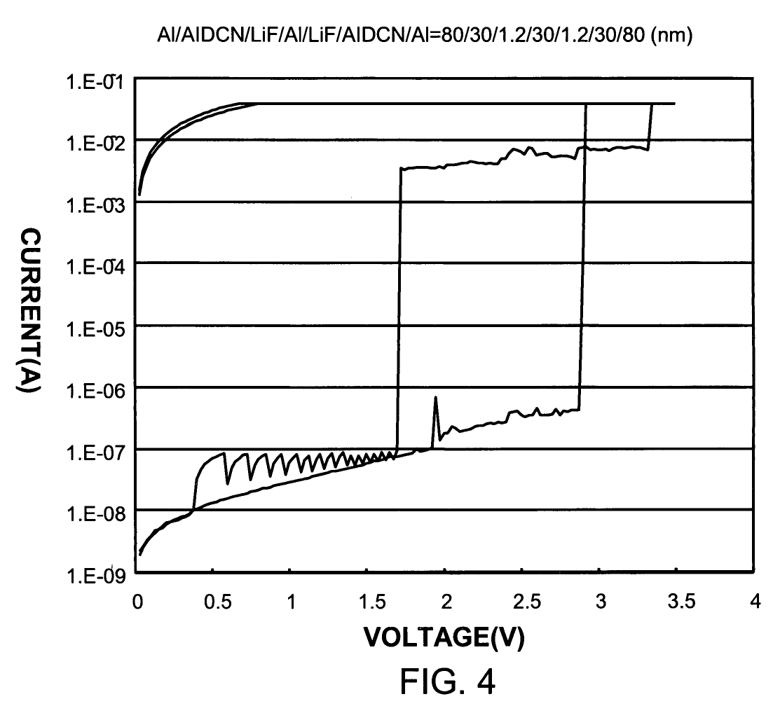

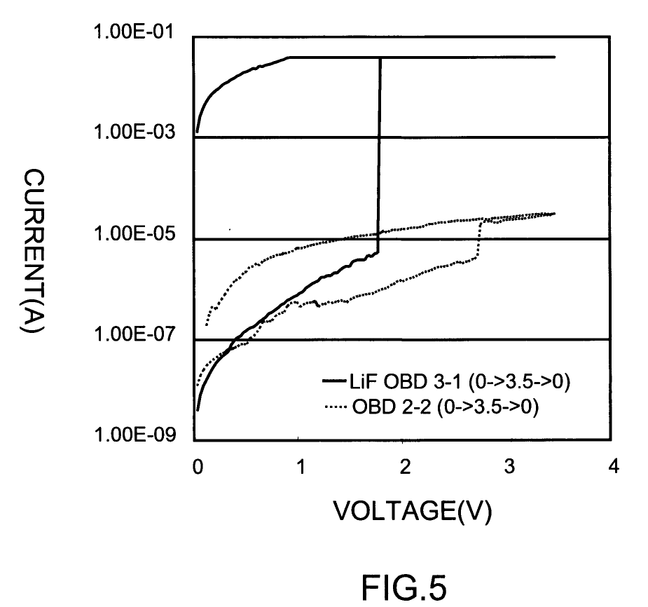

FIGS. 4 to 7 correspond to comparisons of technical results between the organic bistable memory according to the invention and the related prior art. In the invention, the organic bistable memory may provide a current on/off ratio of about 5×10⁶, as shown in FIG. 4. FIG. 5 shows a comparison between the organic bistable memory in the invention and in the prior art. Lithium fluoride of 1.2 nm thickness is used to form the dielectric layer. The whole structure is formed, from top to bottom, with Al, AIDCN, LiF, Al, LiF, AIDCN and Al with thicknesses of 80 nm, 30 nm, 1.2 nm, 30 nm, 1.2 nm, 30 nm and 80 nm, respectively.

After comparison with the bistable memory of the prior art, it can be seen that the organic bistable memory provided by the invention has a larger on-state current, meaning the lithium fluoride dielectrics better enables electron injection to the bistable body in the on state. The off-state currents in the invention and in the prior art are almost the same. As for the current on/off ratio, the value of the organic bistable memory disclosed in the invention is higher than that using the prior art structure by an order of four.

In addition, the organic material AIDCN used in FIG. 5 is of poorer quality and is looked with a light yellow color. The structure disclosed in the invention may screen the reduced on/off ratio effect caused by poor quality organic material.

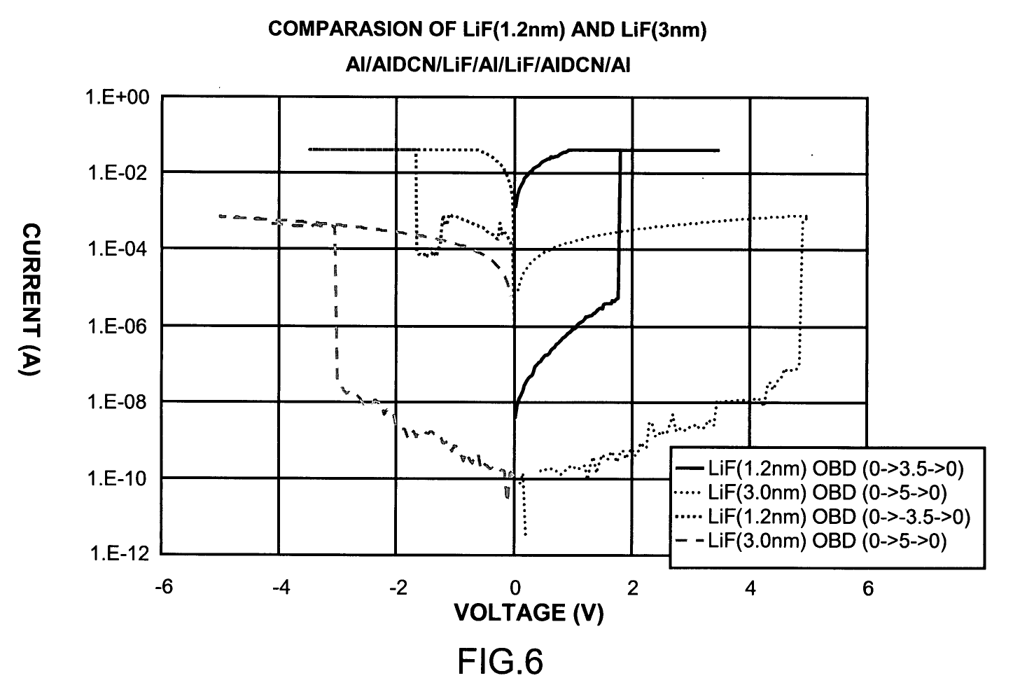

When the thickness of the dielectric layer is varied, the voltage-current relation of the organic bistable transistor has significant variation, which may be seen in FIG. 6. In this figure, it is found that when the thickness of the LiF thin film is varied from 1.2 nm to 3 nm, there are three significant distinctive features, which are stated as follows.

First, their on-state current and off-state current are both decreased. Second, their on-off ratios are increased. Third, the turn-on voltage (when the off state is switched to the on state) is increased to about 4.7V. These three features indicate that too thick of a LiF layer presents its insulating characteristics on its I-V characteristic curve.

In addition, it can be also found from FIG. 6 that the organic bistable memory with 3 nm thick LiF has a longer retention time than an organic bistable memory without a LiF layer. The organic bistable memory with LiF may suffer more tests before shorting failure of the device, which indicates that the addition of the dielectric layer has a further shielding or reduction effect on poor quality material, which has a negative effect on retention time and shorting failure of the device.

FIG. 6 also indicates that the thickness of the dielectric layer may be used to adjust the turn-on voltage, which contributes great flexibility in the optimization of device characteristics and design of voltage specification without needing to change materials and thickness of the organic layer. Also, the required vaporizing process time may be shortened.

Another result of the organic bistable memory of the invention is that variation in the on/off current ratio may be shielded or reduced. In FIGS. 4 to 6 it can be seen that the organic bistable memory with the dielectric layer has a stable current on/off ratio and an order over 10⁵, which allows for a significantly increased degree of independence from the conditions of the manufacturing process.

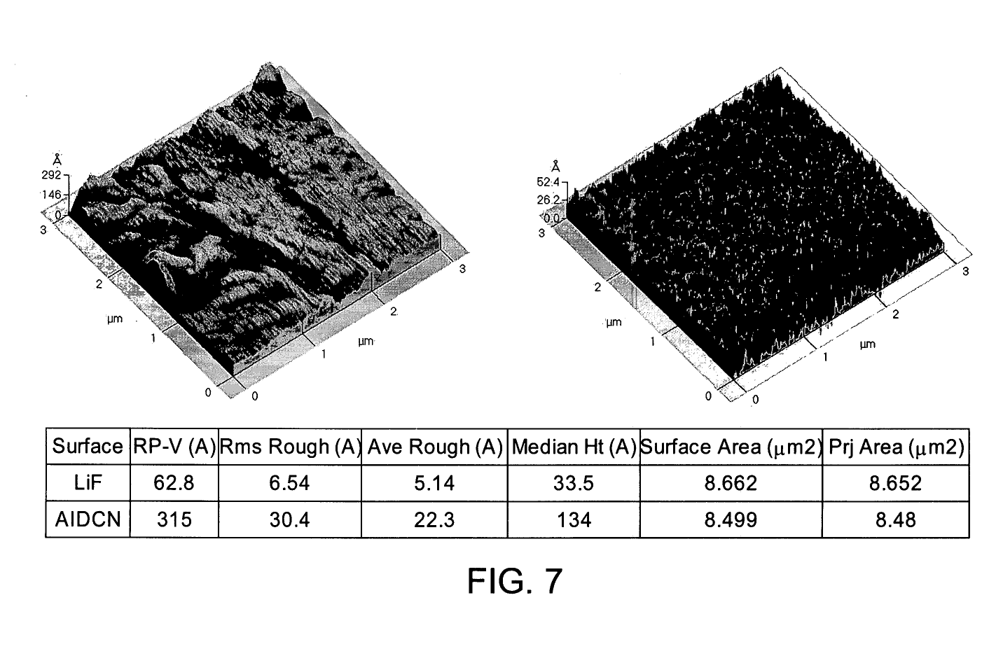

Another result of the organic bistable memory with the dielectric layer is that the surface of the AIDCN with the LiF layer has better flatness than the surface of the AIDCN without the LiF layer, which may be evidenced by FIG. 7. It can be seen that the dielectric layer LiF has a protective or planarizing effect on the surface of the organic layer AIDCN.

The manufacturing process of the organic bistable memory with the dielectric layer according to the invention is described as follows, in which the second embodiment of the memory device as mentioned above is used for description.

First, five metal shadow masks needed for the vaporization process in the manufacturing of organic bistable memory are prepared, in which a first electrode Al, a first organic layer AIDCN, a conductive layer, Al nano-particle layer, a second organic layer AIDCN and a second electrode Al are vaporized.

Next, a 1 μm thick thermal oxide layer SiO2 is grown on a Si wafer to insulate the bare Si substrate and overlaying layers on the thermal oxide layer. Al and LiF layers are deposited in the same process chamber while the organic layer is vaporized in another process chamber.

A detailed description for manufacturing the organic bistable memory with the dielectric layer is given as follows.

Step 1: directing the wafer with the thermal oxide layer into an Al-deposition process chamber of a thermal evaporator and vaporizing a first electrode layer with a first metal mask.

Step 2: transferring the wafer into an organic material process chamber and vaporizing a first organic layer with a second metal mask.

Step 3: replacing the vent of the AL deposition chamber with Al Nano-Particle metal mask and evacuating the chamber.

Step 4: transferring the wafer into the Al-deposition process chamber and vaporizing in turn a first dielectric layer, a conductive layer and a second dielectric layer with a third metal. In this step, the LiF layer is vaporized to about 0.5 nm-50 nm. In forming the conductive layer, the process chamber must have a pressure of about 1×10⁻⁵ torr, as stated in Appl. Phys. Lett. 2003 proposed by Dr. Yang, so as to produce Al nano-particles. A crucible for evaporation of the LiF layer is placed in the same room with an Al crucible.

Step 5: returning the wafer into the organic material process chamber and vaporizing a second organic layer with a fourth metal mask.

Step 6: replacing the vent of the AL deposition chamber with a fifth metal mask and evacuating the chamber under 1×10⁻⁶ torr.

Step 7: transferring the wafer into the Al-deposition process chamber and vaporizing a second electrode with a fifth metal mask.

A LiF-OBD device structure (Al/AIDCN/LiF/Nano-Al/LiF/AIDCN/Al) is thus formed.

According to the invention, the organic bistable memory with the dielectric layer may shield or reduce the effect on the I-V curve due to a material of poor quality and variations in processing conditions, to increase the retention time and reduce the possibility of shorting failure of the device.

While the preferred embodiments of the invention have been described in the above, they are not deemed as a limitation in the scope of the invention. Further, all modifications and variations deduced by the embodiments of the invention are to be considered within the scope of invention.

1. A organic bistable memory operating between a high impedance state and a low impedance state, comprising:
a bistable body comprising an organic material of high impedance and a conductive layer of low impedance and enabling the memory to operate between the high impedance state and the low impedance state when a voltage is applied on the organic bistable memory;
at least one first dielectric layer formed on one surface of the bistable body;
at least one second dielectric layer formed on the other surface of the bistable body;
a first electrode formed below the first dielectric layer; and
a second electrode formed above the second dielectric layer.

2. The organic bistable memory as recited in claim 1, wherein the first and second dielectric layers are respectively formed with a compound formed with an element from IA group and an element from VIIA group, or an element from IIA group and an element from VIA group.

3. The organic bistable memory as recited in claim 1, wherein the first and second dielectric layers have a thickness of about 0.5 nm to 50 nm.

4. The organic bistable memory as recited in claim 1, wherein the bistable body comprises an organic material of high impedance and a conductive layer of low impedance.

5. The organic bistable memory as recited in claim 1, wherein the bistable body comprises a material having nanoparticles of high conduction and a material of low conduction distributed therein.

6. An organic bistable memory switched between a high impedance state and a low impedance state comprising:
a bistable body consisting of an organic material of low impedance and a conductive layer of high impedance, comprising a conductive layer having a dielectric layer formed on one side thereof and a dielectric layer formed on the other side thereof and enabling the memory to operate between the high impedance state and the low impedance state when a voltage is applied on the organic bistable memory;
at least one first dielectric layer formed on one surface of the conductive layer;
at least one second dielectric layer formed on the other surface of the conductive layer;
a first electrode formed below the first dielectric layer; and
a second electrode formed above the second dielectric layer.

7. The organic bistable memory as recited in claim 6, wherein the first and second dielectric layers are respectively formed with a compound formed with an element from Group IA and an element from Group VIIA or an element from Group IIA and an element from Group VIA.

8. The organic bistable memory as recited in claim 6, wherein each of the first and second dielectric layers has a thickness of about 0.5 nm to 50 nm.

9. A method of manufacturing an organic bistable memory comprising the steps of:
forming a first electrode;
forming a first organic layer over the first electrode forming at least one first dielectric layer, a conductive layer and at least one second dielectric layer on the first organic layer, wherein an evaporation crucible for the dielectric layer and an evaporation crucible for the conductive layer are placed in the same chamber;
forming a second organic layer over the second dielectric layer; and
forming a second electrode over the second organic layer.

10. The organic bistable memory as recited in claim 9, wherein the first and second dielectric layers are respectively formed with a compound formed with an element from Group IA and an element from Group VIIA or an element from Group IIA and an element from Group VIA.

11. The organic bistable memory as recited in claim 9, wherein each of the first and second dielectric layers has a thickness of about 0.5 nm to 50 nm.
